(19) United States
(12) Patent Application Publication
(10) Pub. No.: US 2020/0122324 A1
(43) Pub. Date: Apr. 23, 2020

(54) DEVICE AND METHOD FOR THE ELECTRICAL TESTING OF AN ELECTRICAL COMPONENT

(71) Applicant: Franka Emika GmbH, München (DE)

(72) Inventors: Tobias Ende, München (DE); Michael Haas, Todtenweis-Sand (DE); Saskia Golz, München (DE); Sven Parusel, München (DE); Simon Haddadin, München (DE)

(21) Appl. No.: 16/606,597

(22) PCT Filed: Apr. 18, 2018
(86) PCT No.: PCT/EP2018/059899

§ 371 Date: Oct. 18, 2019

(30) Foreign Application Priority Data
Apr. 23, 2017 (DE) 10 2017 003 900.3

(51) Int. Cl. B25J 9/16; G01R 1/067

(52) U.S. Cl. CPC B25J 9/1661; G01R 1/06794; B25J 9/1687

(57) ABSTRACT

The invention relates to a device for the electrical testing of an electrical component (BT), which has a first electromechanical interface (S1), wherein the electrical component (BT) is provided with the first electromechanical interface (S1) thereof at a target position (POS_{S1}) and a target orientation (O_{S1}), the device including: a force-regulated and/or impedance-regulated and/or admittance-regulated first robot manipulator having a first effector, a control unit for controlling/regulating the first robot manipulator, the control unit being designed and constructed to execute the following first control program: controlling the first robot manipulator in such a manner that the first robot manipulator guides the second electromechanical interface (S2) along a predefined trajectory m with a predefined target orientation (O_{target,S2}(R_{T})) to the first electromechanical interface (S1) of the electrical component (BT) provided at the position (POS_{S1}), wherein, upon the mechanical connection of the first electromechanical interface (S1) to the second electromechanical interface (S2), executing force-regulated and/or impedance-regulated and/or admittance-regulated tilting motions about the target orientation (O_{target,S2}(R_{T})) and/or rotary motions and/or translational motions of the second electromechanical interface (S2) by the first robot manipulator; and an analysis means connected to the second electromechanical interface (S2), the analysis means being designed and constructed to execute an analysis program for the electrical testing of the electrical component (BT) electromechanically connected to the analysis means via the first and second electromechanical interfaces.

### CROSS-REFERENCE TO RELATED APPLICATIONS

The present application is the U.S. National Phase of PCT/EP2018/059899, filed on 18 Apr. 2018, which claims priority to German Patent Application No. 10 2017 003 900.3, filed on 23 Apr. 2017, the entire contents of which are incorporated herein by reference.

### BACKGROUND

### Field

The invention relates to a device and to a method for the automated electrical testing of electrical components. The term “electrical component” in this case includes all objects having electrical connections, electrical lines, electrical component parts, electrical circuits, etc. In particular, this also includes complete electrical and/or electronic devices, for example, a smart phone, a computer keyboard, etc.

### Related Art

DE 699 12 589 T2 relates to a testing device for testing electronic modules.

DE 10 2011 112 532 A1 relates to a testing device for a plurality of battery cells, particularly a vehicle battery.

DE 203 21 782 UI relates to a system for recording, influencing, and utilizing robotic movements.

DE 20 2014 100 803 UI relates to a measuring device for a steering wheel in a motor vehicle.

DE 10 2010 012 598 A1 relates to a process module library for programming a manipulator process.

DE 10 2011 011 660 B4 relates to an installation device, which is formed to combine a second workpiece with a first workpiece, which is arranged at a fixed position.

### SUMMARY

The object of the invention is to indicate a device as well as a method with which electrical testing of such electrical components can be implemented in a manner that is more effective, reliable, quicker, and economical.

The invention results from the features of the main claims. Advantageous further embodiments and designs are the subject matter of the dependent claims. Further features, application options, and advantages of the invention result from the following description and explanation of example embodiments of the invention, which are represented in the figures.

A first aspect of the invention relates to a device according to a first alternative for the electrical testing of an electrical component BT, which has a first electromechanical interface S1, wherein the electrical component BT is provided with the first electromechanical interface S1 thereof at a target position POS_{S1} and a target orientation O_{S1}, the device including: a force-regulated and/or impedance-regulated and/or admittance-regulated first robot manipulator having a first effector, wherein the first effector has a second electromechanical interface S2 compatible with the first interface S1; a control unit for controlling/regulating the first robot manipulator, the control unit being designed and constructed to execute the following first control program: controlling the first robot manipulator in such a manner that said manipulator guides the second electromechanical interface S2 along a predefined trajectory T with a predefined target orientation O_{target,S2}(R_{T}) to the first electromechanical interface S1 of the electrical component BT provided at the position POS_{S1}, wherein the target orientation O_{target,S2}(R_{T}) of the second electromechanical interface S2 is defined along the trajectory T for locations R_{T} of the trajectory T, wherein, for the mechanical connection of the first electromechanical interface S1 to the second electromechanical interface S2, force-regulated and/or impedance-regulated and/or admittance-regulated tilting motions about the target orientation O_{target,S2}(R_{T}) and/or rotary motions and/or translational motions of the second electromechanical interface S2 are executed by the first robot manipulator until a specified limit value condition G for a torque acting at the first effector and/or a specified limit value condition G2 of a force acting at the first effector is reached or exceeded and/or a provided force/torque signature and/or a position/velocity/acceleration signature is reached or exceeded at the first effector, which indicates/indicate that the mechanical connection of a first and second electromechanical interface is successfully completed within predefined tolerances, wherein the first interface S1 and the second interface S2 have mutually assigned electrical contacts, which are correspondingly electrically connected after the successful connection of the first and second electromechanical interface; and an analysis means connected to the second electromechanical interface S2, the analysis means being designed and constructed to execute an analysis program for the electrical testing of the electrical component BT electromechanically connected to the analysis means via the first and second electromechanical interfaces.

In this variant, the electrical component BT is provided with a first electromechanical interface S1 thereof at a target position POS_{S1} with a target orientation O_{S1}. In this case, the target position POS_{S1} and target orientation O_{S1} information relates to interface S1. Because the component and the interface S1 are advantageously securely connected to one another, this accordingly results as well in a position and orientation of the component BT.

The following applies to the embodiments of the concept of the invention mentioned in this description. The tilting motions and/or the rotary motions and/or the translational motions are advantageously periodic motions. Depending on the application case, the rotary motions and/or tilting motions and translational motions may also be periodic motions or a combination of aperiodic and periodic motions. The tilting motions advantageously occur relative to the target orientation O_{target,S2}(R_{T}) of the effector about one, two, or three tilting axes, wherein the corresponding tilt angle is advantageously in an angle range of up to ±1°, ±2°, ±5°, ±7°, ±10°, ±12°, ±15° with respect to the target orientation O_{target,S2}(R_{T}). The tilting motions and/or the translational motions are advantageously closed motions. With a closed tilting motion, it is understood in this case that the following applies to an orientation O(t) of interface S2: O(t₀)=O(t₁) where t₀<t₀. With a closed translational motion, it is understood in this case that the trajectory or at least a projection of the trajectory results in a closed curve. The rotary motions occur about an axis of rotation advantageously periodically and advantageously at an angle-of-rotation range of ±1°, ±2°, ±5°, ±7°, ±10°, ±12°, ±15°. The tilting motions/rotary motions/translational motions are advantageously executed continually. They are particularly executed advantageously upon connection and/or during the connection of the first and second electromechanical interface, i.e. particularly when there is already a mechanical contact between the first and second interface. In particular, the execution of the rotary and/or tilting motions is used to connect the first interface S1 to the second interface S2 reliably and with lower force and/or torque effort and thus in a material-protecting manner.

The first interface S1 may be, for example, an electrical socket, wherein the second interface S2 is an electrical plug correspondingly matched to the socket. In particular, the first interface S1 and the second interface S2 are electrical plug connections or turning connections matched to one another. The first interface S1 and the second interface S2 may particularly be designed such that they connect a number n of different electrical conductors with one another, where n≥1.

The term “trajectory” is understood in this case to be a trajectory, particularly a three-dimensional trajectory.

The term “signature” in this case describes a predefined parameter data set with assigned values and/or interval limits and/or a predefined time response of a predefined parameter data set for identifying the successful completion of the mechanical connection of the two electromechanical interfaces S1 and S2. Thus, the “signature” describes a combination of parameters and/or the time response thereof. For example, a predefined force-time response may thus define the successful completion of the connection process.

The analysis means advantageously includes a unit for voltage measurement, for current measurement, for capacity measurement, for resistance measurement, for recording an analysis of logical states of the component BT, or a combination thereof. The analysis means advantageously includes a processor, on which the analysis program runs, which controls the analysis means and makes it capable of executing an electronic test of the component BT according to the analysis program. Depending on the electrical or electronic complexity of the component BT, the electronic testing may include the most varied of aspects and tests. The analysis means is preferably suitable for carrying out a quality control or a production control of the component BT. The analysis means is advantageously connected to the second electromechanical interface by a wireless connection or wired connection.

An advantageous further embodiment of the device is characterized in that a force-regulated and/or impedance-regulated and/or admittance-regulated second robot manipulator with a second effector is available, which is designed and constructed to pick up, handle, and release the electrical component BT, wherein the control unit is designed and constructed for controlling/regulating the second robot manipulator and for executing the following second control program: controlling the second robot manipulator such that the second robot manipulator picks up an electrical component BT to be tested which is provided on an interface, and the second robot manipulator places and releases the component BT with a first electromechanical interface S1 thereof being held at the target position POS_{S1} with the target orientation O_{S1}, or the second robot manipulator holds and thus provides the component with a first electromechanical interface S1 thereof being held at the target position POS_{S1} with the target orientation O_{S1}.

In this embodiment, the second robot manipulator is essentially used to provide the interface of the component BT at the target position POS_{S1} with the target orientation O_{S1}.

A further aspect of the invention relates to a device according to a second alternative for the electrical testing of an electrical component BT, which has a first electromechanical interface S1, the device including: an interface for providing the electrical component BT to be tested; a force-regulated and/or impedance-regulated and/or admittance-regulated first robot manipulator having a first effector, wherein the first effector has a second electromechanical interface S2 compatible with the first interface S1; a force-regulated and/or impedance-regulated and/or admittance-regulated second robot manipulator with a second effector, which is designed and constructed to pick up, handle, and release the electrical component BT; a control unit for coordinated controlling/regulating the first and second robot manipulator, the control unit being designed and constructed to execute the following third control program: controlling the second robot manipulator such that said robot manipulator picks up the electrical component provided at the interface, controlling/regulating the first and the second robot manipulator such that the first and the second electromechanical interface are guided, in a coordinated manner, for the purpose of the complete mechanical connection thereof to one another, wherein, for the mechanical connection of the first electromechanical interface S1 to the second electromechanical interface S2, force-regulated and/or impedance-regulated and/or admittance-regulated tilting motions and/or rotary motions and/or translational motions are executed, or coordinated force-regulated and/or impedance-regulated and/or admittance-regulated tilting motions and/or rotary motions and/or translational motions are executed by the first robot manipulator and by the second robot manipulator until a specified limit value condition G3/G4 for a torque acting at the first/second effector and/or a specified limit value condition G5/G6 of a force acting at the first/second effector is reached or exceeded and/or a provided force/torque signature and/or a position/velocity/acceleration signature is reached or exceeded at the first/second effector, which indicates/indicate that the mechanical connection of a first and second electromechanical interface is successfully completed within predefined tolerances, wherein the first and the second electromechanical interface have mutually assigned electrical contacts, which are correspondingly electrically connected after the successful connection of the first and second electromechanical interface; and an analysis means connected to the second electromechanical interface S2, the analysis means being designed and constructed to execute an analysis program for the electrical testing of the electrical component BT connected via the first and second electromechanical interfaces.

In contrast to the device according to the first alternative, the device according to the second alternative includes the first robot manipulator and the second robot manipulator, which are controlled and/or regulated in a coordinated manner, i.e. dependent on one another, by the control unit, particularly to execute the third control program. In terms of this coordinated use of the two robot manipulators to achieve a common object, their coordination plays a decisive role. The common handling of the robot manipulators must thus be matched to one another. The coordination advantageously includes the formation of sub-objects and/or sub-targets, the transfer to the corresponding robot manipulators, and an exchange of information in order to synchronize the robot manipulators. Various approaches are known in the prior art for the coordinated control of the two robot manipulators. A combined control response of the robot manipulators advantageously results from a superposing of attracting and repelling components. The control unit advantageously has a coordinator C. In order to coordinate the reactions of the two robot manipulators, said reactions are initially weighted and totaled vectorially to form a total reaction in the coordinator C. According to a first variant, each response of one of the robot manipulators has a predefined impact on the total response of both robot manipulators. The total response is subsequently advantageously limited to a maximum response (described by corresponding parameters). Thus, each response of one of the robot manipulators is included in the total response as a percentage. According to a second variant, a prioritized superposition is proposed, in which the weighted reactions of the respective robot manipulator are totaled in a sequence of the greatest impacting factors. Further embodiments of the coordinated control of the robot manipulators can be found in the prior art, to which reference is made herein.

An advantageous further embodiment of the devices according to the first or second alternative are characterized in that the first robot manipulator or the second robot manipulator or a third robot manipulator connected to the device has a mechanical interface, which is designed for mechanical input into a haptic/manual input interface connected to the component BT to be tested, and/or has an electrical contact K, which is designed for electrical signal input into an electrical mating-contact GK connected electrically to the component BT to be tested, wherein the control unit is designed and constructed to execute the following fourth control program: controlling/regulating the first/second/third robot manipulator as a function of the analysis program such that, during execution of the analysis program, predefined haptic/manual inputs are carried out in the haptic/manual input interface by the mechanical interface, and/or that, during execution of the analysis program, the electrical contact K has electrical contact with the electrical mating-contact GK and, in the electrically connected state, predefined electrical signal inputs take place in the mating-contact GT as a function of the analysis program via the contact K.

In this further embodiment, it is thus possible, particularly as a function of the respective work step in the analysis program, to carry out mechanical inputs or electrical signals in the component BT, provided the component has corresponding input interfaces. Impact can be made on the electrical and/or logical state of the component BT by the inputs; furthermore, the reliability and functionality of the input interfaces can be correspondingly tested.

The contact K and the correspondingly designed mating-contact GK are advantageously formed as multiconductor interfaces such that electrical signals between the component BT and the analysis unit can be simultaneously transmitted or received via a plurality of electrical lines.

An advantageous further embodiment of the device according to the first alternative is characterized in that the analysis means is connected to the control unit, and the control unit is designed and constructed such that the second control program is executed as a function of a current program step in the analysis program.

An advantageous further embodiment of the device according to the first alternative or second alternative is characterized in that the control unit is designed and constructed to execute the following fifth control program: after an ending of the analysis program (for the electrical testing of the component BT), controlling of the second robot manipulator for disconnecting the electromechanical connection of the first and second electromechanical interfaces such that the second electromechanical interface S2 is guided, under the execution of force-regulated and/or impedance-regulated and/or admittance-regulated tilting motions relative to a target orientation O_{target}(R_{A}) and/or rotary motions and/or translational motions, from the first electromechanical interface S1 along a predefined starting trajectory A, wherein the target orientation O_{target}(R_{A}) of the second interface S2 is defined along the starting trajectory A for locations R_{A} of the trajectory A. The execution of the indicated motions is used to separate interface S2 from interface S1 with less force and thus in a material-protecting manner.

An advantageous further embodiment of the device according to the second alternative is characterized in that the control unit is designed and constructed to execute the following sixth control program: after an ending of the analysis program (for the electrical testing of the component BT), disconnecting the connection of the first and second electromechanical interfaces through coordinated control of the first and of the second robot manipulator such that the first electromechanical interface S1 or the second electromechanical interface S2 are moved away from each other under the execution of force-regulated and/or impedance-regulated and/or admittance-regulated tilting motions and/or rotatory motions and/or translational motions, or that the first electromechanical interface S1 and the second electromechanical interface S2 are moved away from one another under the execution of coordinated force-regulated and/or impedance-regulated and/or admittance-regulated tilting motions and/or rotatory motions and/or translational motions. The execution of the indicated motions is used to separate interface S2 from interface S1 with less force and thus in a material-protecting manner. In contrast with the previous further embodiment of the device, these motions of the first and of the second robot manipulator, however, occur here in a matched and coordinated manner.

An advantageous further embodiment of the device according to the first or second alternative is characterized in that the electrical component to be tested is a PC board, a PC board populated with electrical components, or an electrical device.

An advantageous further embodiment of the device according to the first or second alternative is characterized in that the device has a data interface to a data network, and the device is designed and constructed to load one or more control programs from the data network. The data network may be the Internet, a local data network, an ad hoc data network, etc.

An advantageous further embodiment of the device according to the first or second alternative is characterized in that the device is designed and constructed to load control and regulation parameters to the control programs from the data network.

An advantageous further embodiment of the device according to the first or second alternative is characterized in that the device is designed and constructed to load control and regulation parameters to the control programs via a local input interface and/or via a teach-in process, in which the robot manipulator is guided manually.

An advantageous further embodiment of the device according to the first or second alternative is characterized in that the device is designed and constructed to control the loading of control programs and/or of related control and regulation parameters from the data network from a remote station, which is likewise connected to the data network.

An advantageous further embodiment of the device according to the first or second alternative is characterized in that the device is designed and constructed to transmit control programs available locally on the device and/or related control and regulation parameters upon request or actively to other equivalent devices and/or other users via the data network.

An advantageous further embodiment of the device according to the first or second alternative is characterized in that the device is designed and constructed such that control programs available locally on the screwing device with the related control and regulation parameters are started from a remote station, which is likewise connected to the data network.

An advantageous further embodiment of the device according to the first or second alternative is characterized in that the remote station and/or the local input interface has a human-machine interface, which is designed and constructed for the input of control programs and/or related control and regulation parameters, and/or for the selection of control programs and/or related control and regulation parameters from a plurality of available control programs and/or related control and regulation parameters.

An advantageous further embodiment of the device according to the first or second alternative is characterized in that the human-machine interface enables inputs via a drag-and-drop input on a touchscreen, a guided input dialogue, a keyboard, a computer mouse, a haptic input interface, a virtual-reality unit, an augmented reality unit of an acoustic input interface, body tracking, on the basis of electromyography data, on the basis of electroencephalography data, via a neuronal interface to the brain, or a combination thereof.

An advantageous further embodiment of the invention according to the first or second alternative is characterized in that the human-machine interface is designed and constructed to output auditory, visual, haptic, olfactory, tactile, electrical feedback, or a combination thereof.

A further aspect of the invention relates to a method according to a first alternative for the electrical testing of an electrical component BT, which has a first electromechanical interface S1, wherein the electrical component BT is provided with the first electromechanical interface S1 thereof at a target position POS_{S1} and a target orientation O_{S1}, the method including: providing a force-regulated and/or impedance-regulated and/or admittance-regulated first robot manipulator having a first effector, wherein the first effector has a second electromechanical interface S2 compatible with the first interface S1; providing a control unit for controlling/regulating the first robot manipulator, the control unit executing the following first control program: controlling the first robot manipulator in such a manner that said the first robot manipulator guides the second electromechanical interface S2 along a predefined trajectory T with a predefined target orientation O_{target,S2}(R_{T}) to the first electromechanical interface S1 of the electrical component BT provided at the position POS_{S1}, wherein the target orientation O_{target,S2}(R_{T}) of the second electromechanical interface S2 is defined along the trajectory T for locations R_{T} of the trajectory T, wherein, for the mechanical connection of the first electromechanical interface S1 to the second electromechanical interface S2, executing force-regulated and/or impedance-regulated and/or admittance-regulated tilting motions about the target orientation O_{target,S2}(R_{T}) and/or rotary motions and/or translational motions of the second electromechanical interface S2 by the first robot manipulator until a specified limit value condition G1 for a torque acting at the first effector and/or a specified limit value condition G2 of a force acting at the first effector is reached or exceeded and/or a provided force/torque signature and/or a position/velocity/acceleration signature is reached or exceeded at the first effector, which indicates/indicate that the mechanical connection of a first and second electromechanical interfaces is successfully completed within predefined tolerances, wherein the first electromechanical interface S1 and the second electromechanical interface S2 have mutually assigned electrical contacts, which are correspondingly electrically connected after the successful connection of the first and second electromechanical interface; and providing an analysis means connected to the second electromechanical interface S2, the analysis means executing an analysis program for the electrical testing of the electrical component BT connected via the first and second electromechanical interfaces.

An advantageous further embodiment of the method according to a first alternative is characterized in that a force-regulated and/or impedance-regulated and/or admittance-regulated second robot manipulator with a second effector is available, which is designed and constructed to pick up, handle, and release the electrical component BT, wherein the control unit is designed for controlling/regulating the second robot manipulator and for executing the following second control program: controlling the second robot manipulator such that the second robot manipulator picks up an electrical component BT to be tested which is provided on an interface, and the second robot manipulator releases and correspondingly places the component BT with a first electromechanical interface S1 thereof being held at the target position POS_{S1} with the target orientation O_{S1}, or the second robot manipulator holds and thus provides the component with a first electromechanical interface S1 thereof being held at the target position POS_{S1} with the target orientation O_{S1}.

A further aspect of the invention relates to a method according to a second alternative for the electrical testing of an electrical component BT, which has a first electromechanical interface S1, the method including: providing an interface for providing the electrical component BT to be tested; providing a force-regulated and/or impedance-regulated and/or admittance-regulated first robot manipulator having a first effector, wherein the first effector has a second electromechanical interface S2 compatible with the first interface S1; providing a force-regulated and/or impedance-regulated and/or admittance-regulated second robot manipulator with a second effector, which is designed and constructed to pick up, handle, and release the electrical component BT; providing a control unit for coordinated controlling/regulating the first and second robot manipulators, the control unit executing the following third control program: controlling the second robot manipulator such that said the second robot manipulator picks up the electrical component provided at the interface, controlling/regulating the first and the second robot manipulators in a coordinated manner such that the first and the second electromechanical interfaces are guided, in a coordinated manner, for the purpose of the complete mechanical connection thereof to one another, wherein, for the mechanical connection of the first electromechanical interface S1 to the second electromechanical interface S2, force-regulated and/or impedance-regulated and/or admittance-regulated tilting motions and/or rotary motions and/or translational motions are executed by the first robot manipulator or by the second robot manipulator, or coordinated force-regulated and/or impedance-regulated and/or admittance-regulated tilting motions and/or rotary motions and/or translational motions are executed by the first robot manipulator and the second robot manipulator until a specified limit value condition G3/G4 for a torque acting at the first/second effector and/or a specified limit value condition G5/G6 of a force acting at the first/second effector is reached or exceeded and/or a provided force/torque signature and/or a position/velocity/acceleration signature is reached or exceeded at the first/second effector, which indicates/indicate that the mechanical connection of a first and second electromechanical interface is successfully completed within predefined tolerances, wherein the first and the second interface have mutually assigned electrical contacts, which are correspondingly electrically connected after the successful connection of the first and second electromechanical interface; providing an analysis means connected to the second electromechanical interface S2, the analysis means executing an analysis program for the electrical testing of the electrical component BT connected via the first and second electromechanical interfaces.

In contrast to the method according to the first alternative, a coordinated control of the first and of the second robot manipulator takes place with the method according to the second alternative, as previously stated multiple times.

An advantageous further embodiment of the method according to the first or second alternative is characterized in that the first robot manipulator or the second robot manipulator or a third robot manipulator connected to the device has a mechanical interface, which is designed for mechanical input into a haptic/manual input interface connected to the component BT to be tested, and/or has an electrical contact K, which is designed for electrical signal input into an electrical mating-contact GK connected electrically to the component BT to be tested, wherein the control unit executes the following fourth control program: controlling/regulating the first/second/third robot manipulator as a function of the analysis program such that, during execution of the analysis program, predefined haptic/manual inputs are carried out in the haptic/manual input interface by the mechanical interface; and/or that, during execution of the analysis program, the electrical contact K has electrical contact with the electrical mating-contact GK and, in the electrically connected state, predefined electrical signal inputs take place in the mating-contact GT as a function of the analysis program via the contact K.

Advantageously with the method according to the first alternative, the analysis means is connected to the control unit, and the control unit executes the second control program as a function of a current program step in the analysis program.

An advantageous further embodiment of the method according to the first alternative or second alternative is characterized in that the control unit executes the following fifth control program: after an ending of the analysis program, controlling of the second robot manipulator for disconnecting the electromechanical connection of the first and second electromechanical interfaces such that the second electromechanical interface S2 is guided, under the execution of force-regulated and/or impedance-regulated and/or admittance-regulated tilting motions relative to a target orientation O_{target}(R_{A}) and/or rotary motions and/or translational motions, from the first electromechanical interface S1 along a predefined starting trajectory A, wherein the target orientation O_{target}(R_{A}) of the second interface S2 is defined along the starting trajectory A for locations R_{A} of the trajectory A.

An advantageous further embodiment of the method according to the second alternative is characterized in that the control unit executes the following sixth control program: after an ending of the analysis program, disconnecting the connection of the first and second electromechanical interfaces through coordinated control of the first and of the second robot manipulator such that the first electromechanical interface S1 or the second electromechanical interface S2 are moved away from each other under the execution of force-regulated and/or impedance-regulated and/or admittance-regulated tilting motions and/or rotatory motions and/or translational motions; or that the first electromechanical interface S1 and the second electromechanical interface S2 are moved away from one another under the execution of coordinated force-regulated and/or impedance-regulated and/or admittance-regulated tilting motions and/or rotatory motions and/or translational motions.

An advantageous further embodiment of the method according to the first or second alternative is characterized in that the respective device has a data interface to a data network, and the device is designed and constructed to load one or more control programs from the data network.

An advantageous further embodiment of the method according to the first or second alternative is characterized in that the respective device loads control and regulation parameters to the control programs from the data network.

An advantageous further embodiment of the method according to the first or second alternative is characterized in that the respective device loads control and regulation parameters to the control programs available locally on the device via a local input interface and/or via a teach-in process, in which the first and/or second or third robot manipulator is guided manually.

An advantageous further embodiment of the method according to a first or second alternative is characterized in that the loading of control programs and/or of related control and regulation parameters from the data network to the respective device is controlled from a remote station, which is likewise connected to the data network.

An advantageous further embodiment of the method according to the first or second alternative is characterized in that control programs available locally on the device with the related control and regulation parameters are started from a remote station, which is likewise connected to the data network.

Advantages and advantageous further embodiments of the proposed method result from an analogous and corresponding transfer of the statements made regarding the devices according to the invention. Reference is hereby made thereto.

A further aspect of the invention relates to a computer system with a data processing device, wherein the data processing device is designed such that a method, as previously described, is executed on the data processing device.

A further aspect of the invention relates to a digital memory medium with electronically readable control signals, wherein the control signals can cooperate with a programmable computer system such that a method, as previously described, is executed.

A further aspect of the invention relates to a computer program product with a memory code, stored on a machine-readable carrier, for executing the method, as previously described, when the program code is implemented on a data processing device.

A further aspect of the invention relates to a computer program with memory codes for executing the method, as previously described, when the program is running on a data processing device. To this end, the data processing device may be designed as any computer system known from the prior art.

Other advantages, features, and details result from the following description, in which at least one example embodiment is described in detail—optionally with reference to the drawing.

Equivalent, similar, and/or functionally equivalent parts have been given the same reference numerals.

### BRIEF DESCRIPTION OF THE DRAWINGS

In the drawings:

FIG. 1 shows a schematic representation of the configuration of a proposed device; and

FIG. 2 shows a schematic flowchart for a proposed method.

### DETAILED DESCRIPTION

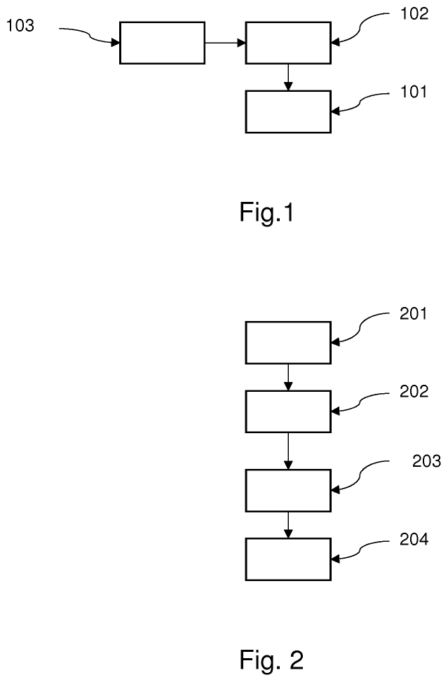

FIG. 1 shows a schematic representation of the configuration of a proposed device for the electrical testing of an electrical component BT, which has a first electromechanical interface S1, wherein the electrical component BT is provided with the first electromechanical interface S1 thereof at a target position POS_{S1} and a target orientation O_{S1}. The device includes a force-regulated and impedance-regulated first robot manipulator 101 having a first effector, wherein the first effector has a second electromechanical interface S2 compatible with the first interface S1, a control unit 102 for controlling/regulating the first robot manipulator 101 according to a predefined control program. The control program 102 has a processor, on which the control program runs. The control unit 102 is designed and constructed to execute the following first control program: controlling the first robot manipulator 101 in such a manner that said manipulator guides the second electromechanical interface S2 along a predefined trajectory T with a predefined target orientation O_{target,S2}(R_{T}) to the first electromechanical interface S1 of the electrical component BT provided at the position POS_{S1}, wherein the target orientation O_{target,S2}(R_{T}) of the second electromechanical interface S2 is defined along the trajectory T for locations R_{T} of the trajectory T, wherein, for the mechanical connection of the first electromechanical interface S1 to the second electromechanical interface S2, force-regulated and/or impedance-regulated and/or admittance-regulated tilting motions about the target orientation O_{target,S2}(R_{T}) and/or rotary motions and/or translational motions of the second electromechanical interface S2 are executed by the first robot manipulator 101 until a specified limit value condition G1 for a torque acting at the first effector and/or a specified limit value condition G2 of a force acting at the first effector is reached or exceeded and/or a provided force/torque signature and/or a position/velocity/acceleration signature is reached or exceeded at the first effector, which indicates/indicate that the mechanical connection of a first and second electromechanical interface is successfully completed within predefined tolerances, wherein the first interface S1 and the second interface S2 have mutually assigned electrical contacts, which are correspondingly electrically connected after the successful connection of the first and second electromechanical interface.

The device further includes an analysis means 103 connected to the second electromechanical interface S2, the analysis means 103 being designed and constructed to execute an analysis program for the electrical testing of the electrical component BT electromechanically connected to the analysis means 103 via the first and second electromechanical interfaces.

FIG. 2 shows a schematic flowchart for a proposed method for the electrical testing of an electrical component BT, which has a first electromechanical interface S1, wherein the electrical component BT is provided 201 with the first electromechanical interface S1 thereof at a target position POS_{S1} and a target orientation O_{S1}, the method including: providing a force-regulated and impedance-regulated first robot manipulator 101 having a first effector, wherein the first effector has a second electromechanical interface S2 compatible with the first interface S1; providing a control unit 102 for controlling/regulating the first robot manipulator 101, the control unit 102 executing the following first control program: controlling 202 the first robot manipulator 101 in such a manner that said the first robot manipulator guides the second electromechanical interface S2 along a predefined trajectory T with a predefined target orientation O_{target,S2}(R_{T}) to the first electromechanical interface S1 of the electrical component BT provided at the position POS_{S1}, wherein the target orientation O_{target,S2}(R_{T}) of the second electromechanical interface S2 is defined along the trajectory T for locations R_{T} of the trajectory T, and wherein, for the mechanical connection of the first electromechanical interface S1 to the second electromechanical interface S2, executing 203 force-regulated and/or impedance-regulated and/or admittance-regulated tilting motions about the target orientation O_{target,S2}(R_{T}) and/or rotary motions and/or translational motions of the second electromechanical interface S2 by the first robot manipulator (101) until a specified limit value condition G 1 for a torque acting at the second effector and/or a specified limit value condition G2 of a force acting at the second effector is reached or exceeded and/or a provided force/torque signature and/or a position/velocity/acceleration signature is reached or exceeded at the second effector, which indicates/indicate that the mechanical connection of a first and second electromechanical interfaces is successfully completed within predefined tolerances, wherein the first electromechanical interface S1 and the second electromechanical interface S2 have mutually assigned electrical contacts, which are correspondingly electrically connected after the successful connection of the first and second electromechanical interfaces; and providing an analysis means connected to the second electromechanical interface S2, the analysis means executing 204 an analysis program for the electrical testing of the electrical component BT connected via the first and second electromechanical interfaces.

Although the invention has been illustrated and explained in more detail by using preferred example embodiments, the invention is not limited by the disclosed examples and other variations may be derived by one of ordinary skill in the art without extending beyond the protective scope of the invention. It is thus clear that a plurality of variation options exist. It is likewise clear that example embodiments actually only represent examples, which are not to be interpreted in any manner as a limitation, for example, of the protective scope, the use options, or the configuration of the invention. Rather, the previous description and the description of figures should make one of ordinary skill in the art capable of specifically implementing the example embodiments, wherein one of ordinary skill in the art with knowledge of the disclosed concept of the invention can undertake various changes, for example, with respect to the function or the arrangement of individual elements listed in an example embodiment, without going beyond the scope of protection, which is defined by the claims and the legal equivalents thereof such as, for example, more extensive explanations in the description.

1. A device for electrical testing of an electrical component BT, the electrical component BT comprising a first electromechanical interface S1 that is provided at a target position POS_{S1} and a target orientation O_{S1}, the device comprising:
a force-regulated and/or impedance-regulated and/or admittance-regulated first robot manipulator having a first effector, wherein the first effector has a second electromechanical interface S2 compatible with the first electromechanical interface S1;
a control unit to control or regulate the first robot manipulator for mechanical connection of the first electromechanical interface S1 to the second interface S2, wherein the control unit is designed and constructed to execute a first control program to perform operations comprising:
controlling the first robot manipulator in such a manner that the first robot manipulator guides the second electromechanical interface S2 along a predefined trajectory T with a predefined target orientation O_{target,S2}(R_{T}) to the first electromechanical interface S1 of the electrical component BT provided at the target position POS_{S1}, wherein the target orientation O_{target,S2}(R_{T}) of the second electromechanical interface S2 is defined along the trajectory T for locations R_{T} of the trajectory T; and
executing force-regulated and/or impedance-regulated and/or admittance-regulated tilting motions about the target orientation O_{target,S2}(R_{T}) and/or rotary motions and/or translational motions of the second electromechanical interface S2 by the first robot manipulator until a specified limit value condition G1 for a torque acting at the first effector and/or a specified limit value condition G2 of a force acting at the first effector is reached or exceeded, and/or until a provided force/torque signature and/or a position/velocity/acceleration signature is reached or exceeded at the first effector, indicating that mechanical connection of the first electromechanical interface S1 and second electromechanical interface S2 is successfully completed within predefined tolerances, wherein the first electromechanical interface S1 and the second electromechanical interface S2 have mutually assigned electrical contacts, the electrical contacts correspondingly electrically connected after the successful connection of the first electromechanical interface S1 and second electromechanical interface S2; and
an analysis means connected to the second electromechanical interface S2, the analysis means being designed and constructed to execute an analysis program for electrical testing of the electrical component BT electromechanically connected to the analysis means via the first electromechanical interface S1 and second electromechanical interface S2.

2. The device according to claim 1, further comprising a force-regulated and/or impedance-regulated and/or admittance-regulated second robot manipulator with a second effector is available, the second effector designed and constructed to pick up, handle, and release the electrical component BT, wherein the control unit is designed and constructed to control or regulate the second robot manipulator, wherein the control unit is designed and constructed to execute a second control program to perform operations comprising:
controlling the second robot manipulator such that the second robot manipulator picks up the electrical component BT to be tested which is provided on an interface, and the second robot manipulator places and releases the electrical component BT with the first electromechanical interface S1 thereof being held at the target position POS_{S1} with the target orientation O_{S1}, or the second robot manipulator holds and thus provides the electrical component BT with the first electromechanical interface S1 thereof being held at the target position POS_{S1} and the target orientation O_{S1}.

3. (canceled)

4. The device according to claim 1, wherein the first robot manipulator or the second robot manipulator or a third robot manipulator connected to the device has a mechanical interface, the mechanical interface is designed for mechanical input into a haptic/manual input interface connected to the electrical component BT to be tested, and/or has an electrical contact K, the electrical contact K is designed for electrical signal input into an electrical mating-contact GK connected electrically to the component BT to be tested; and
wherein the control unit is designed and constructed to execute a fourth control program to perform operations comprising: controlling or regulating the first robot manipulator, the second robot manipulator, or the third robot manipulator as a function of the analysis program such that, during execution of the analysis program, predefined haptic/manual inputs are carried out in the haptic/manual input interface by the mechanical interface; and/or that, during execution of the analysis program, the electrical contact K has electrical contact with the electrical mating-contact GK and, in electrically connected state, predefined electrical signal inputs take place in the mating-contact GT as a function of the analysis program via the contact K.

5. The device according to claim 1, wherein the control unit is designed and constructed to execute a fifth control program to perform operations comprising:
after ending of the analysis program, controlling the second robot manipulator to disconnect the electromechanical connection of the first electromechanical interface S1 and second electromechanical interface S2 such that the second electromechanical interface S2 is guided, under execution of force-regulated and/or impedance-regulated and/or admittance-regulated tilting motions relative to a target orientation O_{target}(R_{A}) and/or rotary motions and/or translational motions, from the first electromechanical interface S1 along a predefined starting trajectory A, wherein the target orientation O_{target}(R_{A}) of the second electromechanical interface S2 is defined along the starting trajectory A for locations R_{A} of the trajectory A.

6. The device according to claim 1, wherein the control unit is designed and constructed to execute a sixth control program to perform operations comprising:
after ending of the analysis program, disconnecting the connection of the first and second electromechanical interfaces through coordinated control of the first robot manipulator and the second robot manipulator such that the first electromechanical interface S1 or the second electromechanical interface S2 are moved away from each other under the execution of force-regulated and/or impedance-regulated and/or admittance-regulated tilting motions and/or rotatory motions and/or translational motions, or such that the first electromechanical interface S1 and the second electromechanical interface S2 are moved away from one another under the execution of coordinated force-regulated and/or impedance-regulated and/or admittance-regulated tilting motions and/or rotatory motions and/or translational motions.

7. A method of electrical testing of an electrical component BT, the electrical component BT comprising a first electromechanical interface S1 that is provided at a target position POS_{S1} and a target orientation O_{S1}, the method comprising:
providing a force-regulated and/or impedance-regulated and/or admittance-regulated first robot manipulator having a first effector, wherein the first effector has a second electromechanical interface S2 compatible with the first interface S1;
providing a control unit to control the first robot manipulator, wherein the control unit executes a first control program to perform operations comprising:
controlling the first robot manipulator in such a manner that the first robot manipulator guides the second electromechanical interface S2 along a predefined trajectory T with a predefined target orientation O_{target,S2}(R_{T}) to the first electromechanical interface S1 of the electrical component BT provided at the position POS_{S1}, wherein the target orientation O_{target,S2}(R_{T}) of the second electromechanical interface S2 is defined along the trajectory T for locations R_{T} of the trajectory T;
executing force-regulated and/or impedance-regulated and/or admittance-regulated tilting motions about the target orientation O_{target,S2}(R_{T}) and/or rotary motions and/or translational motions of the second electromechanical interface S2 by the first robot manipulator until a specified limit value condition G1 for a torque acting at the first effector and/or a specified limit value condition G2 of a force acting at the first effector is reached or exceeded, and/or until a provided force/torque signature and/or a position/velocity/acceleration signature is reached or exceeded at the first effector, indicating that the mechanical connecting of a first electromechanical interface S1 and second electromechanical interface S2 is successfully completed within predefined tolerances, wherein the first electromechanical interface S1 and the second electromechanical interface S2 have mutually assigned electrical contacts, the electrical contacts correspondingly electrically connected after the successful connection of the first and second electromechanical interface; and
providing an analysis means connected to the second electromechanical interface S2, the analysis means executing an analysis program for the electrical testing of the electrical component BT connected via the first electromechanical interface S1 and second electromechanical interface S2.

8. The method according to claim 7, wherein a force-regulated and/or impedance-regulated and/or admittance-regulated second robot manipulator with a second effector is available, the second effector designed and constructed to pick up, handle, and release the electrical component BT, wherein the control unit is constructed for controlling or regulating the second robot manipulator and for executing a second control program to perform operations comprising:
controlling the second robot manipulator such that the second robot manipulator picks up the electrical component BT to be tested which is provided on an interface, and the second robot manipulator releases and correspondingly places the electrical component BT with a first electromechanical interface S1 thereof being held at the target position POS_{S1} with the target orientation O_{S1}, or the second robot manipulator holds and thus provides the electrical component BT with a first electromechanical interface S1 thereof being held at the target position POS_{S1} with the target orientation O_{S1}.

9. (canceled)

10. The method according to claim 7,
wherein the first robot manipulator or the second robot manipulator or a third robot manipulator connected to the device has a mechanical interface, the mechanical interface designed for mechanical input into a haptic/manual input interface connected to the component BT to be tested, and/or has an electrical contact K, which is designed for electrical signal input into an electrical mating-contact GK connected electrically to the component BT to be tested,
wherein the control unit executes a fourth control program to perform operations comprising: controlling or regulating the first robot manipulator, the second robot manipulator, or the third robot manipulator as a function of the analysis program such that, during execution of the analysis program, predefined haptic/manual inputs are carried out in the haptic/manual input interface by the mechanical interface, and/or such that, during execution of the analysis program, the electrical contact K has electrical contact with the electrical mating-contact GK and, in the electrically connected state, predefined electrical signal inputs take place in the mating-contact GT as a function of the analysis program via the contact K.

11. The method according to claim 7, wherein the control unit executes a fifth control program to perform operations comprising:
after an ending of the analysis program, controlling the second robot manipulator for disconnecting the electromechanical connection of the first electromechanical interface S1 and second electromechanical interface S2 such that the second electromechanical interface S2 is guided, under the execution of force-regulated and/or impedance-regulated and/or admittance-regulated tilting motions relative to a target orientation O_{target}(R_{A}) and/or rotary motions and/or translational motions, from the first electromechanical interface S1 along a predefined starting trajectory A, wherein the target orientation O_{target}(R_{A}) of the second electromechanical interface S2 is defined along the starting trajectory A for locations R_{A} of the trajectory A.

12. The method according to claim 7, wherein the control unit executes a sixth control program to perform operations comprising:
after an ending of the analysis program, disconnecting the connection of the first electromechanical interface S1 and second electromechanical interface S2 through coordinated control of the first robot manipulator and the second robot manipulator such that the first electromechanical interface S1 or the second electromechanical interface S2 are moved away from each other under the execution of force-regulated and/or impedance-regulated and/or admittance-regulated tilting motions and/or rotatory motions and/or translational motions, or such that the first electromechanical interface S1 and the second electromechanical interface S2 are moved away from one another under the execution of coordinated force-regulated and/or impedance-regulated and/or admittance-regulated tilting motions and/or rotatory motions and/or translational motions.

13. A device for electrical testing of an electrical component BT, the electrical component BT having a first electromechanical interface S1, the device comprising:
an interface to provide the electronic component BT to be tested;
a force-regulated and/or impedance-regulated and/or admittance-regulated first robot manipulator having a first effector, wherein the first effector has a second electromechanical interface S2 compatible with the first interface S1;
a force-regulated and/or impedance-regulated and/or admittance-regulated second robot manipulator having a second effector, the second effector designed and constructed to pick up, handle, and release the electrical component BT;
a control unit for coordinated controlling or regulating the second robot manipulator, wherein the control unit is designed and constructed to execute a third control program to perform operations comprising:
controlling the second robot manipulator such that the second robot manipulator picks up the electrical component provided at the interface;
controlling or regulating the first robot manipulator and the second robot manipulator in a coordinated manner such that the first electromechanical interface S1 and the second electromechanical interface S2 are guided, in a coordinated manner, for a purpose of complete mechanical connection thereof to one another, wherein, for mechanical connection of the first electromechanical interface S1 to the second electromechanical interface S2,
i) force-regulated and/or impedance-regulated and/or admittance-regulated tilting motions and/or rotary motions and/or translational motions are executed by the first robot manipulator or by the second robot manipulator, or
ii) coordinated force-regulated and/or impedance-regulated and/or admittance-regulated tilting motions and/or rotary motions and/or translational motions are executed by the first robot manipulator and by the second robot manipulator,
until a specified limit value condition G3/G4 for a torque acting at the first effector/second effector and/or a specified limit value condition G5/G6 of a force acting at the first effector/second effector is reached or exceeded and/or a provided force/torque signature and/or a position/velocity/acceleration signature is reached or exceeded at the first effector/second effector, indicating that the mechanical connection of a first electromechanical interface S1 and the second electromechanical interface S2 is successfully completed within predefined tolerances, wherein the first electromechanical interface S1 and the second electromechanical interface S2 have mutually assigned electrical contacts, the electrical contacts correspondingly electrically connected after the successful connection of the first electromechanical interface S1 and the second electromechanical interface S2; and
an analysis means connected to the second electromechanical interface S2, the analysis means being designed and constructed to execute an analysis program for electrical testing of the electrical component BT connected via the first electromechanical interface S1 and second electromechanical interface S2.

14. The device according to claim 13, wherein the first robot manipulator or the second robot manipulator or a third robot manipulator connected to the device has a mechanical interface, the mechanical interface is designed for mechanical input into a haptic/manual input interface connected to the electrical component BT to be tested, and/or has an electrical contact K, the electrical contact K is designed for electrical signal input into an electrical mating-contact GK connected electrically to the component BT to be tested; and
wherein the control unit is designed and constructed to execute a fourth control program to perform operations comprising: controlling or regulating the first robot manipulator, the second robot manipulator, or the third robot manipulator as a function of the analysis program such that, during execution of the analysis program, predefined haptic/manual inputs are carried out in the haptic/manual input interface by the mechanical interface, and/or that, during execution of the analysis program, the electrical contact K has electrical contact with the electrical mating-contact GK and, in electrically connected state, predefined electrical signal inputs take place in the mating-contact GT as a function of the analysis program via the contact K.

15. The device according to claim 13, wherein the control unit is designed and constructed to execute a fifth control program to perform operations comprising:
after ending of the analysis program, controlling the second robot manipulator to disconnect the electromechanical connection of the first electromechanical interface S1 and second electromechanical interface S2 such that the second electromechanical interface S2 is guided, under execution of force-regulated and/or impedance-regulated and/or admittance-regulated tilting motions relative to a target orientation O_{target}(R_{A}) and/or rotary motions and/or translational motions, from the first electromechanical interface S1 along a predefined starting trajectory A, wherein the target orientation O_{target}(R_{A}) of the second electromechanical interface S2 is defined along the starting trajectory A for locations R_{A} of the trajectory A.

16. The device according to claim 13, wherein the control unit is designed and constructed to execute a sixth control program to perform operations comprising:
after an ending of the analysis program, disconnecting the connection of the first and second electromechanical interfaces through coordinated control of the first robot manipulator and the second robot manipulator such that the first electromechanical interface S1 or the second electromechanical interface S2 are moved away from each other under the execution of force-regulated and/or impedance-regulated and/or admittance-regulated tilting motions and/or rotatory motions and/or translational motions, or such that the first electromechanical interface S1 and the second electromechanical interface S2 are moved away from one another under the execution of coordinated force-regulated and/or impedance-regulated and/or admittance-regulated tilting motions and/or rotatory motions and/or translational motions.

17. A method of electrical testing of an electrical component BT, the electrical component BT having a first electromechanical interface S1, the method comprising:
providing an interface to provide the electronic component BT to be tested;
providing a force-regulated and/or impedance-regulated and/or admittance-regulated first robot manipulator having a first effector, wherein the first effector has a second electromechanical interface S2 compatible with the first electromechanical interface S1;
providing a force-regulated and/or impedance-regulated and/or admittance-regulated second robot manipulator having a second effector, the second effector designed and constructed to pick up, handle, and release the electrical component BT;
providing a control unit for coordinated controlling or regulating the first robot manipulator and the second robot manipulator, wherein the control unit executes a third control program to perform operations comprising:
controlling the second robot manipulator such that the second robot manipulator picks up the electrical component provided at the interface;
controlling or regulating the first robot manipulator and the second robot manipulator such that the first electromechanical interface S1 and the second electromechanical interface S2 are guided, in a coordinated manner, for the purpose of the complete mechanical connection thereof to one another, wherein, for the mechanical connection of the first electromechanical interface S1 to the second electromechanical interface S2,
i) force-regulated and/or impedance-regulated and/or admittance-regulated tilting motions and/or rotary motions and/or translational motions are executed by the first robot manipulator or by the second robot manipulator, or
ii) coordinated force-regulated and/or impedance-regulated and/or admittance-regulated tilting motions and/or rotary motions and/or translational motions are executed by the first robot manipulator and by the second robot manipulator,
until a specified limit value condition G3/G4 for a torque acting at the first effector/second effector and/or a specified limit value condition G5/G6 of a force acting at the first effector/second effector is reached or exceeded and/or a provided force/torque signature and/or a position/velocity/acceleration signature is reached or exceeded at the first/second effector, indicating that the mechanical connection of a first electromechanical interface S1 and second electromechanical interface S2 is successfully completed within predefined tolerances, wherein the first electromechanical interface S1 and the second electromechanical interface S2 have mutually assigned electrical contacts, the electrical contacts correspondingly electrically connected after the successful connection of the first electromechanical interface S1 and second electromechanical interface S2; and
providing an analysis means connected to the second electromechanical interface S2, the analysis means executing an analysis program for electrical testing of the electrical component BT connected via the first electromechanical interface S1 and second electromechanical interface S2.

18. The method according to claim 17,
wherein the first robot manipulator or the second robot manipulator or a third robot manipulator connected to the device has a mechanical interface, the mechanical interface designed for mechanical input into a haptic/manual input interface connected to the component BT to be tested, and/or has an electrical contact K, which is designed for electrical signal input into an electrical mating-contact GK connected electrically to the component BT to be tested,
wherein the control unit executes a fourth control program to perform operations comprising: controlling or regulating the first robot manipulator, the second robot manipulator, or the third robot manipulator as a function of the analysis program such that, during execution of the analysis program, predefined haptic/manual inputs are carried out in the haptic/manual input interface by the mechanical interface, and/or such that, during execution of the analysis program, the electrical contact K has electrical contact with the electrical mating-contact GK and, in the electrically connected state, predefined electrical signal inputs take place in the mating-contact GT as a function of the analysis program via the contact K.

19. The method according to claim 17, wherein the control unit executes a fifth control program to perform operations comprising:
after an ending of the analysis program, controlling the second robot manipulator for disconnecting the electromechanical connection of the first electromechanical interface S1 and second electromechanical interface S2 such that the second electromechanical interface S2 is guided, under the execution of force-regulated and/or impedance-regulated and/or admittance-regulated tilting motions relative to a target orientation O_{target}(R_{A}) and/or rotary motions and/or translational motions, from the first electromechanical interface S1 along a predefined starting trajectory A, wherein the target orientation O_{target}(R_{A}) of the second electromechanical interface S2 is defined along the starting trajectory A for locations R_{A} of the trajectory A.

20. The method according to claim 17, wherein the control unit executes a sixth control program to perform operations comprising:
after an ending of the analysis program, disconnecting the connection of the first electromechanical interface S1 and second electromechanical interface S2 through coordinated control of the first robot manipulator and the second robot manipulator such that the first electromechanical interface S1 or the second electromechanical interface S2 are moved away from each other under the execution of force-regulated and/or impedance-regulated and/or admittance-regulated tilting motions and/or rotatory motions and/or translational motions, or such that the first electromechanical interface S1 and the second electromechanical interface S2 are moved away from one another under the execution of coordinated force-regulated and/or impedance-regulated and/or admittance-regulated tilting motions and/or rotatory motions and/or translational motions.
